(19) United States
(12) Patent Application Publication
(10) Pub. No.: US 2018/0223432 A1
(43) Pub. Date: Aug. 9, 2018

(54) POLYSILICON PREPARATION APPARATUS

(71) Applicant: HANWHA CHEMICAL CORPORATION, Seoul (KR)

(72) Inventors: Sung Eun PARK, Yeosu-si (KR); Hee Dong LEE, Seoul (KR); Jiwoong KIM, Seoul (KR)

(21) Appl. No.: 15/750,260

(22) PCT Filed: Aug. 26, 2016
(86) PCT No.: PCT/KR2016/009541

§ 371 Date: Feb. 5, 2018

(30) Foreign Application Priority Data
Aug. 23, 2015 (KR) 10-2015-0121963

(51) Int. Cl. C23C 16/46; B01J 19/24; C23C 16/24

(52) U.S. Cl. CPC C23C 16/466; C23C 16/24; B01J 19/24

(57) ABSTRACT

The present invention provides a polysilicon manufacturing apparatus that can prevent generation of popcorns in the entire CVD reaction process by cooling an upper portion of a silicon rod where a rod bridge is disposed. A polysilicon manufacturing apparatus according to an exemplary embodiment of the present invention includes: a reactor provided on a base and forming a reaction chamber; a pair of feedthroughs provided in the base and extending into the reaction chamber; rod filaments provided in the feedthroughs in the reaction chamber, connected with each other at upper ends thereof through a rod bridge, and where a silicon rod of polysilicon is formed from a raw material gas through a chemical vapor deposition (CVD) process; and cooling spray nozzles spraying a cooling gas to the silicon rod formed as silicon deposited around the rod bridge and the rod filaments.

### TECHNICAL FIELD

The present invention relates to an apparatus for manufacturing polysilicon. More particularly, the present invention relates to an apparatus for manufacturing polysilicon that cools an upper portion of a silicon rod that is formed by depositing silicon on a rod bridge.

### BACKGROUND ART

Silicon in a polysilicon state (or polycrystalline silicon) is used as a basic material in the solar power generation and semiconductor industries, and the need for polysilicon has rapidly increased together with development of the fields of the corresponding industries. A representative method for manufacturing polysilicon is a silicon precipitation process (or a chemical vapor deposition (CVD) process) that forms polysilicon in a solid state from a silane raw material gas.

Through the silicon precipitation process, silicon particulates are generated through a hydrogen reduction reaction and thermal decomposition from the silane raw material gas at a high temperature, and silicon particulates are formed as a type of polysilicon in a rod or at the surface of a particle and then the polysilicon is precipitated. For example, a Siemens precipitation method using a CVD reactor, a precipitation method using a fluidized bed reactor, and the like may be used.

In a polysilicon manufacturing process, a Siemens CVD reactor is core equipment for a batch process. In the CVD method, silicon filaments, each having a 7 to 10 mm diameter and a 2500-3000 mm length are provided to a reactor, power is applied to the silicon filaments to generate resistance heating, and an injection gas is injected for about 60 to 80 hours in a high-pressure condition such that a silicon rod of a 120 to 150 mm diameter is generated.

Referring to FIG. 16, when silicon is deposited using the CVD reactor, a high-temperature portion may be formed at the surface of the silicon rod depending on a gas flow or a structure of the reactor. A normal silicon rod 161 of (a) of FIG. 16 has a smooth surface, but a silicon rod 162 of (b) has popcorns 163 at high-temperature portions thereof. When the popcorn is formed, the surface is not smooth.

The popcorn 163 deteriorates quality of the silicon rod 162, thereby decreasing a selling price of polysilicon. The popcorn 163 formed in the silicon rod 162 generates an arc. A high-temperature due to the arc melts silicon and the melted silicon is dropped to the bottom of the CVD reactor, causing a discontinuity in the process. That is, the popcorn 163 causes an economic loss in production of polysilicon.

### DISCLOSURE

### Technical Problem

The present invention has been made in an effort to provide a polysilicon manufacturing apparatus that can prevent generation of popcorns in the entire CVD reaction process by cooling an upper portion of a silicon rod where a rod bridge is disposed.

### Technical Solution

A polysilicon manufacturing apparatus according to an exemplary embodiment of the present invention includes: a reactor provided on a base and forming a reaction chamber; a pair of feedthroughs provided in the base and extending into the reaction chamber; rod filaments provided in the feedthroughs in the reaction chamber, connected with each other at upper ends thereof through a rod bridge, and where a silicon rod of polysilicon is formed from a raw material gas through a chemical vapor deposition (CVD) process; and cooling spray nozzles spraying a cooling gas to the silicon rod formed as silicon deposited around the rod bridge and the rod filaments.

The cooling spray nozzle may spray the cooling gas to silicon deposited to the rod bridge from a lower flank side that is distanced by a predetermined gap from the rod bridge.

The cooling spray nozzle may include: pipes provided in upward and downward directions in the reactor or the base; a plate-shaped nozzle body connected to an end of each pipe; and unit nozzle tips provided at a predetermined interval along an external circumference of the nozzle body to spray the cooling gas.

The pipe may be provided upward in the base and connected with the nozzle body at an end of the pipe, and the nozzle body may further include unit nozzle tips that face upward at the opposite side of the pipe.

The pipe may be provided with at least one of gas inlets in the base and through which a raw material gas is injected or provided in the base separately from the gas inlets.

The pipe may be provided downward in an upper portion of the reactor and connected with the nozzle body at an end of the pipe, and the nozzle body may further include unit nozzle tips that face downward at the opposite side of the pipe.

The pipe may include: a gas path supplying the cooling gas to the unit nozzle tips of the nozzle body; and a coolant path provided dually at an external side of the gas path and cooling the cooling gas by circulating the coolant.

The cooling spray nozzle may be formed of one of an Incoloy (Incoloy 800H, Incoloy 800), stainless steel (SS316L, SS316), and a Hastelloy.

The cooling spray nozzle may spray the cooling gas together with the raw material gas.

The cooling gas may include H₂ or HCl.

The cooling gas may further include a silane compound, which is one of dichlorosilane (DCS), trichlorosilane (TCS), monosilane, and silicon tetrachloride (STC).

The cooling gas formed of a raw material gas may be supplied with a temperature that is lower than a surface temperature of the silicon rod.

The cooling spray nozzle may include: a pipe provided in upward and downward directions in the reactor or the base; a nozzle body connected to an end of the pipe and having a predetermined length; and unit nozzle tips arranged along an external circumference of the nozzle body with a height difference set in a length direction of the pipe and spraying the cooling gas.

Among the unit nozzle tips, unit nozzle tips disposed in a lower portion of the pipe may face downward at a predetermined angle, unit nozzle tips disposed in an upper portion of the pipe may face upward at a predetermined angle, and unit nozzle tips disposed at a center of the pipe may face a horizontal direction.

The cooling spray nozzle may include: a pipe provided in upward and downward directions in the reactor or the base; nozzle bodies arranged on the pipe with a height difference set along a height direction of the pipe; and unit nozzle tips arranged along an external circumference of the nozzle body at a predetermined interval and spraying the cooling gas.

### Advantageous Effects

As described, according to the exemplary embodiment of the present invention, cooling spray nozzles are provided and thus a cooling gas is sprayed to a silicon rod provided as silicon that is deposited around a rod bridge and filaments to cool an upper or lower portion of the silicon rod, and accordingly, generation of popcorns in the entire CVD reaction process can be prevented. Therefore, quality of the silicon rod can be improved and a selling price of the polysilicon can be increased.

### DESCRIPTION OF THE DRAWINGS

FIG. 1 is a schematic top plan view of an apparatus for manufacturing polysilicon according to a first exemplary embodiment of the present invention.

FIG. 2 is a schematic perspective view of the polysilicon manufacturing apparatus of FIG. 1.

FIG. 3 is a cross-sectional view of main parts of the polysilicon manufacturing apparatus (e.g., chemical vapor deposition (CVD) reactor manufactured by Siemens) applied to FIG. 2 and FIG. 2.

FIG. 4 is an operation state view illustration a relationship between the silicon rod and the cooling spray nozzles in FIG. 1.

FIG. 5 is a top plan view of cooling spray nozzles applied to the polysilicon manufacturing apparatus according to the first exemplary embodiment of the present invention.

FIG. 6 is a side view of FIG. 5.

FIG. 7 is an operation state view illustrating a relationship between a silicon rod and cooling spray nozzles in a polysilicon manufacturing apparatus according to a second exemplary embodiment of the present invention.

FIG. 8 is a side view of cooling spray nozzles applied to the polysilicon manufacturing apparatus according to the second exemplary embodiment of the present invention.

FIG. 9 is a cross-sectional view of the cooling spray nozzle applied to FIG. 8.

FIG. 10 shows a simulation result of a gas speed distribution when cooling spray directions of the cooling spray nozzle applied to the polysilicon manufacturing apparatus according to the exemplary embodiment of the present invention are respectively 6 directions (a) and 12 directions (b).

FIG. 11 shows a gas speed distribution around the cooling spray nozzles when a cooling spray direction of FIG. 10 is 6 directions (1) and when a cooling spray direction of FIG. 10 is 12 directions (b).

FIG. 12 shows a simulation result of a gas vector distribution diagram for comparison of the cooling spray nozzle arrangements (b and c) according to the first and second exemplary embodiments of the present invention and a conventional method (a).

FIG. 13 shows a simulation result of a gas temperature distribution diagram for comparison of the cooling spray nozzle arrangements (b and c) according to the first and second exemplary embodiments of the present invention and a conventional method (a).

FIG. 14 shows a simulation result of a surface temperature distribution diagram for comparison of the cooling spray nozzle arrangement (b) according to the first and second exemplary embodiments of the present invention and a conventional method (c).

FIG. 15 shows a simulation result of a surface temperature distribution diagram of a temperature of a pipe and a temperature of a cooling spray nozzle in arrangements of the cooling spray nozzles according to the first and second exemplary embodiments of the present invention.

FIG. 16 shows photographs of a normal silicon rod (a) and a silicon rod where popcorns are formed (b) manufactured by a conventional polysilicon manufacturing apparatus.

FIG. 17 is a side view of cooling spray nozzles applied to a polysilicon manufacturing apparatus according to a third exemplary embodiment of the present invention.

FIG. 18 is a side view of cooling spray nozzles applied to a polysilicon manufacturing apparatus according to a fourth exemplary embodiment of the present invention.

FIG. 19 is a side view of cooling spray nozzles applied to a polysilicon manufacturing apparatus according to a fifth exemplary embodiment of the present invention.

FIG. 20 is a side view of cooling spray nozzles applied to a polysilicon manufacturing apparatus according to a sixth exemplary embodiment of the present invention.

<Description of symbols>

| | |
|---|---|
| 10: reactor | 11: reaction chamber |
| 12: bell jar | 13: chamber cover |
| 20: electrical feedthroughs | 21: base |
| 22: gas inlet | 23: gas outlet |
| 24: rod support | 25: electrode |
| 30: rod filament | 31: rod bridge |
| 40: silicon rod | 50, 250: cooling spray nozzle |
| 51, 251: pipe | 52, 252: nozzle body |
| 53, 253, 54, 254: unit nozzle tip | 255: gas path |
| 256: coolant path | 350, 450, 550, 650: cooling spray |
| | nozzle |
| 351, 451, 551, 651: pipe | 352, 452, 552, 652: nozzle body |
| 353, 354, 453, 454, 553, 554, 653, | |
| 654: unit nozzle tip | |
| a1: gas vector | b1, b2, b3: gas vector |
| c1, c2, c3: gas vector | |

### MODE FOR INVENTION

Hereinafter, the present invention will be described more fully with reference to the accompanying drawings, in which example embodiments of the invention are shown. As those skilled in the art would realize, the described embodiments may be modified in various different ways, all without departing from the spirit or scope of the present invention. The drawings and description are to be regarded as illustrative in nature and not restrictive. Like reference numerals designate like elements throughout the specification.

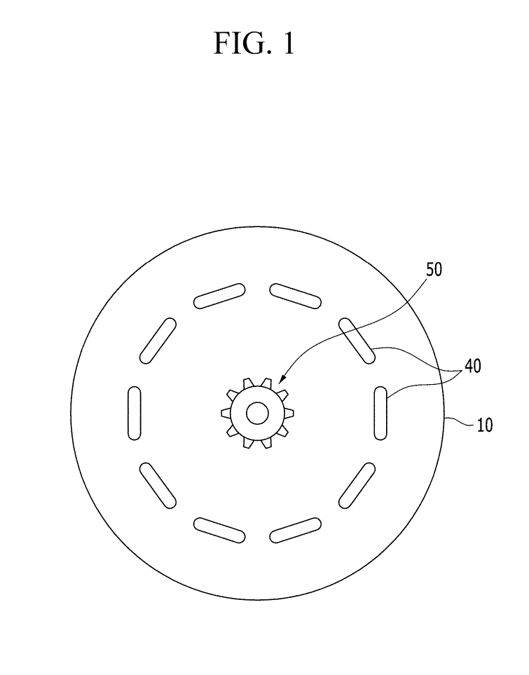

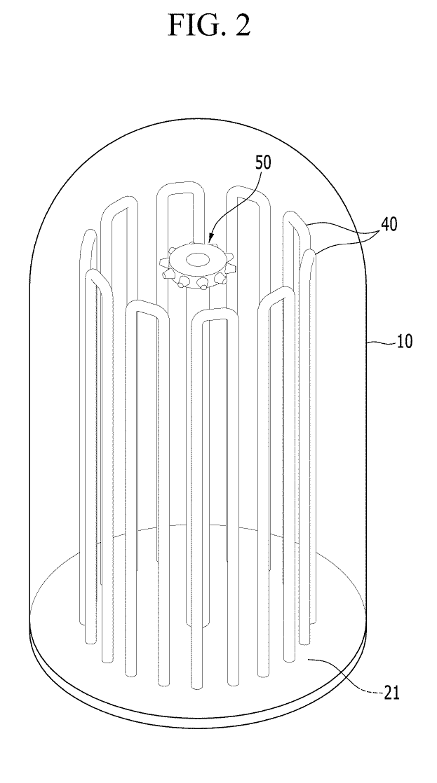

FIG. 1 is a schematic top plan view of a polysilicon manufacturing apparatus according to a first exemplary embodiment of the present invention, and FIG. 2 is a schematic perspective view of the polysilicon manufacturing apparatus of FIG. 1. Referring to FIG. 1 and FIG. 2, the polysilicon manufacturing apparatus according to the first exemplary embodiment of the present invention is provided with a cooling spray nozzle 50 that sprays a cooling gas to a silicon rod 40 that is provided in a reactor 10.

The cooling spray nozzle 50 may spray only a cooling gas, or may spray the cooling gas and a raw material gas. Alternatively, the cooling spray nozzle 50 may spray only the raw material gas when the raw material gas is supplied at a low temperature.

For example, the cooling gas may include H₂ or HCl. H₂ or HCl realize only a cooling effect of the deposited silicon rod 40 without interfering with formation of the silicon rod 40 by the raw material gas. The cooling spray nozzle 50 may cool the silicon rod 40 by spraying the cooling gas with a gas speed of at least 100 m/s. When the raw material gas is supplied at a low temperature and with a fast speed, the raw material gas may be utilized as a cooling gas.

In addition, the cooling gas may further include a silane compound, which is one of dichlorosilane (DCS), trichlorosilane (TCS), monosilane, and silicon tetrachloride (STC). The silane compound such as DCS, TCS, and monosilane realizes the cooling effect of the silicon rod 40 and at the same time serves as a deposition raw material of the silicon rod 40.

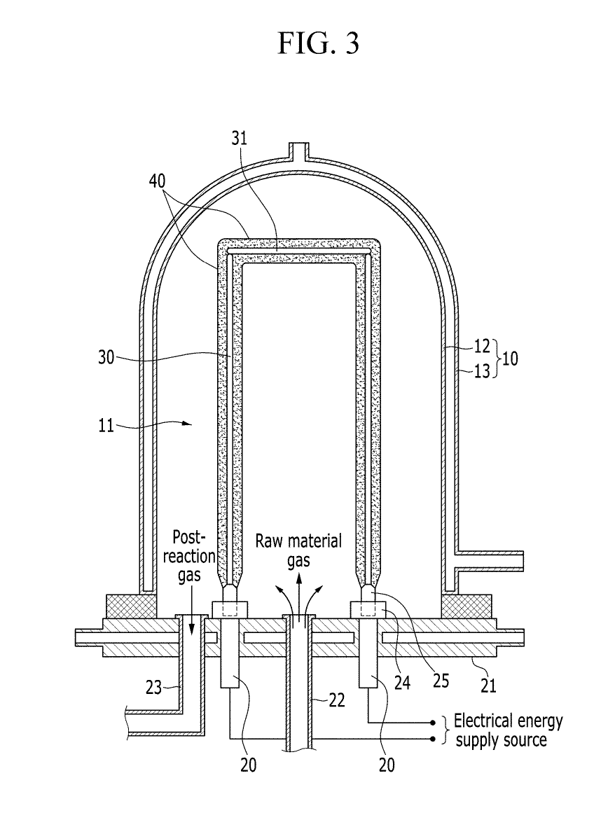

FIG. 3 is a cross-sectional view of main parts of a polysilicon manufacturing apparatus (e.g., a chemical vapor deposition (CVD) reactor manufactured by Siemens) applied to FIG. 1 and FIG. 2. Referring to FIG. 3, the polysilicon manufacturing apparatus includes a reactor 10 that forms a reaction chamber 11, a pair of feedthroughs 20 provided in a base 21, and a pair of rod filaments 30 provided in the feedthroughs 20 and connected to each other through a rod bridge 31 at upper ends thereof.

The reactor 10 provided as a bell-type reactor forms the reaction chamber 11 on the base 21, and is coupled to the base 21 with a gas sealing structure. The reactor 10 includes a bell jar 12 that forms the reaction chamber 11 and a chamber cover 13 distanced from the bell jar 12 to make a coolant flow between the bell jar 12 and the chamber cover 13.

The base 21 forms the reaction chamber 11 by being coupled with the reactor 10, and is provided with a gas inlet 22 and a gas outlet 23. Thus, a raw material gas flows into the reaction chamber 11 through the gas inlet 22 connected to a silicon-containing gas source (not shown), and a gas having undergone a CVD reaction is discharged to the outside of the reaction chamber 11 through the gas outlet 23.

For convenience, the gas inlet 22 is provided in a center of the base 21, but is substantially provided in a plurality of places in the base 21. When the cooling spray nozzle 50 of FIG. 1 and FIG. 2 is provided in the base 21, the gas inlet 22 is provided at the periphery of the cooling spray nozzle 50.

As shown in FIG. 3, when the gas inlet 22 is provided at the center of the base 21, a cooling spray nozzle (not shown) that sprays a cooling gas may be provided by removing a nozzle of the gas inlet 22 and extending a pipe of the gas inlet 22.

A pair of electrode feedthroughs 20 are extended into the reaction chamber 11 from the outside of the base 21. An electrode 25 supported by a rod support 24 is connected to each end of the electric feedthroughs 20.

Rod filaments 30 are provided as a pair or more in the reaction chamber 11. Specifically, the pair of rod filaments 30 are distanced from each other in the reaction chamber 11, and are perpendicularly provided at a distance from each other and connected with each other at upper ends thereof through the rod bridge 31.

In addition, the pair of rod filaments 30 are connected to an external electrical energy supply source through the electrodes 25 and the electrode feedthroughs 20 at lower ends thereof. Thus, the pair of rod filaments 30 form a single electric circuit together with the rod bridge 31.

The rod filaments 30 are supplied with a current through the electrode feedthroughs 20 and the electrode 25, and when a raw material gas is supplied to the reaction chamber 11, the rod filaments 30 are heated and thus a chlorosilane compound included in the raw material gas is thermally decomposed in the reaction chamber 11.

After the decomposition of the chlorosilane compound, polysilicon is formed at the surfaces of the red-hot rod filaments 30 and rod bridge 31 through chemical vapor deposition (CVD). Since the polysilicon is precipitated in the form of polycrystalline at the surface portions of the rod filaments 30 and the rod bridge 31, the silicon rod 40 and the rod bridge 31 can be increased to a desired diameter.

As described, when the polysilicon is precipitated in the rod filaments 30 and the rod bridge 31 and the silicon rod 40 is formed, the cooling spray nozzle 50 sprays the cooling gas to the silicon rod 40 to cool the silicon rod 40 formed as silicon deposited to the periphery of the rod bridge 31.

Considering a precipitation temperature of silicon, trichlorosilane (TCS) (SiHCl₃+H₂→Si+SiHCl₃+SiCl₄+HCl+H₂), dichlorosilane (DCS), silicon tetrachloride (STC), or monosilane (SiH₄→Si+H₂) may be used as the raw material gas.

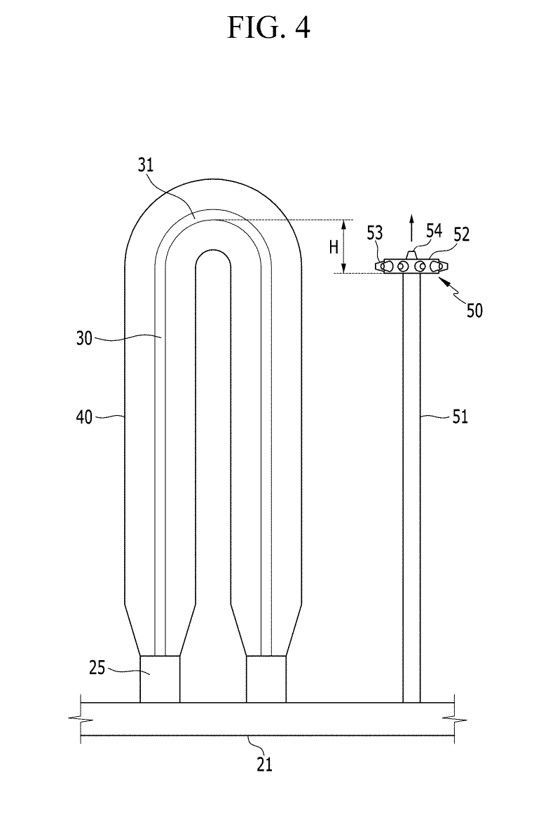

FIG. 4 is an operation state view illustrating a relationship between the silicon rod and the cooling spray nozzle in FIG. 1. Referring to FIG. 4, the cooling spray nozzle 50 sprays the cooling gas to silicon deposited to the rod bridge 31 from a lower flank side that is distanced by a predetermined gap (H) from the rid bridge 31. The cooling spray nozzle 50 is provided upwardly in a lower side of the reactor 10.

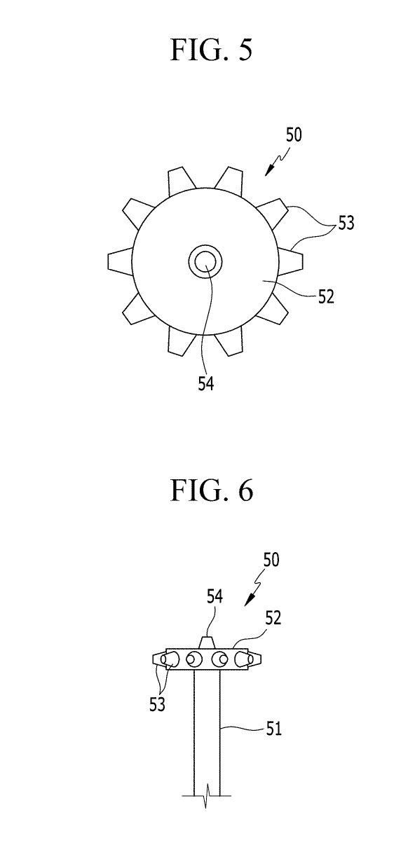

FIG. 5 is a top plan view of the cooling spray nozzle applied to the polysilicon manufacturing apparatus according to the first exemplary embodiment of the present invention, and FIG. 6 is a side view of FIG. 5. For convenience, referring to FIG. 4 to FIG. 6, the cooling spray nozzle 50 includes a pipe 51 provided in the base 21, a plate-shaped nozzle body 52 connected to an end of the pipe 51, and unit nozzle tips 53 provided at a predetermined interval around an external circumference of the nozzle body 52 to spray the cooling gas.

The unit nozzle tips 53 spray the cooling gas to silicon deposited to the rod bridge 31 from a lower flank side that is distanced by a predetermined gap (H) from the rod bridge 31 so as to prevent an upper portion of the rod silicon 40 from being overheated.

Referring to FIG. 1 to FIG. 6, the pipe 51 is provided upwardly from the base 21 and connected with the nozzle body 52 at an end of the base 51. In this case, the pipe 51 may be replaced with a new pipe when no gas inlet is provided at a center of the base 21.

The nozzle body 52 further includes unit nozzle tips 54 that face upward from the opposite side of the pipe 51. The unit nozzle tip 54 that faces upward prevents the upper portion of the cooling spray nozzle 50 from being overheated in the reactor 10 and the reaction chamber 11, thereby preventing an upper portion of the silicon rod 40 from being overheated.

The cooling spray nozzle 50, the pipe 51, the nozzle body 52, and the unit nozzle tips 53 and 54 may be provided as an Incoloy (e.g., Incoloy 800H, Incoloy 800), stainless steel (e.g., SS316L, SS316), or a Hastelloy.

Such a material does not affect purity of precipitated polysilicon, and is stable at a high temperature (e.g., over 1000° C.) and is anti-corrosive and inexpensive.

Hereinafter, a second exemplary embodiment of the present invention will be described. For convenience in description, a description of the same configurations as those of the first exemplary embodiment described above will be omitted, and different configurations from those of the first exemplary embodiment described above will be described.

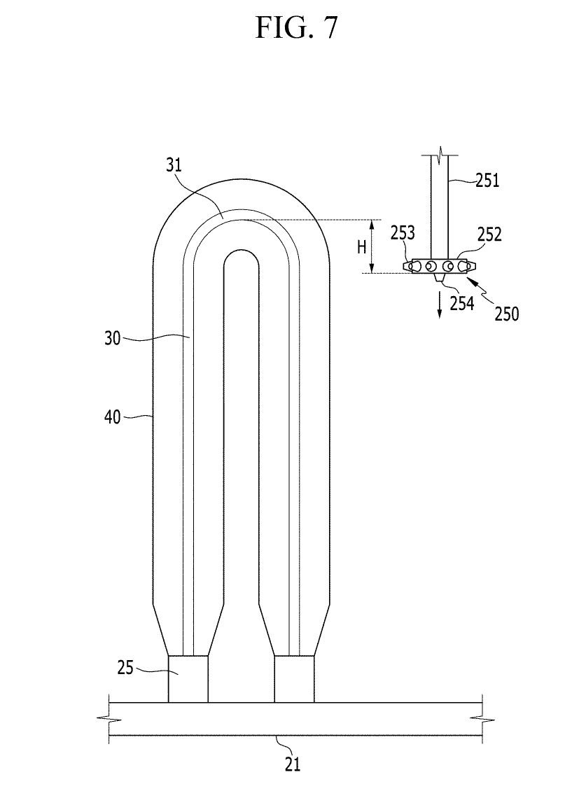

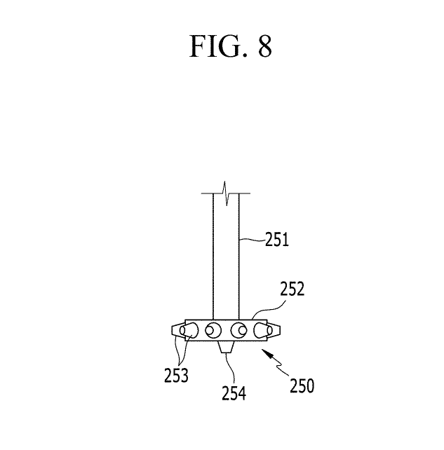

FIG. 7 is an operation state view illustrating a relationship between a silicon rod and a cooling spray nozzle in a polysilicon manufacturing apparatus according to a second exemplary embodiment of the present invention, and FIG. 8 is a side view of the cooling spray nozzle applied to the polysilicon manufacturing apparatus according to the second exemplary embodiment of the present invention.

Referring to FIG. 7 and FIG. 8, the polysilicon manufacturing apparatus according to the second exemplary embodiment of the present invention is provided downwardly from an upper side of a reactor 10.

A cooling spray nozzle 250 includes a pipe 251 provided in the reactor 10, a plate-shaped nozzle body 252 connected to an end of the pipe 251, and unit nozzle tips 253 provided at a predetermined interval around an external circumference of the nozzle body 252 to spray a cooling gas.

The unit nozzle tips 253 spray a cooling gas to silicon deposited to the rod bridge 31 from a lower flank side that is distanced by a predetermined gap (H) from the rod bridge 31 to prevent an upper portion of the rod silicon 40 from being overheated.

The pipe 251 is provided downward from an upper side of the reactor 10 and then connected with the nozzle body 252 at an end thereof. The nozzle body 252 further includes a unit nozzle tip 254 that faces downward at the opposite side of the pipe 251. The unit nozzle tip 254 prevents a lower portion of the cooling spray nozzle 250 from being overheated in the reactor 10 and the reaction chamber 11.

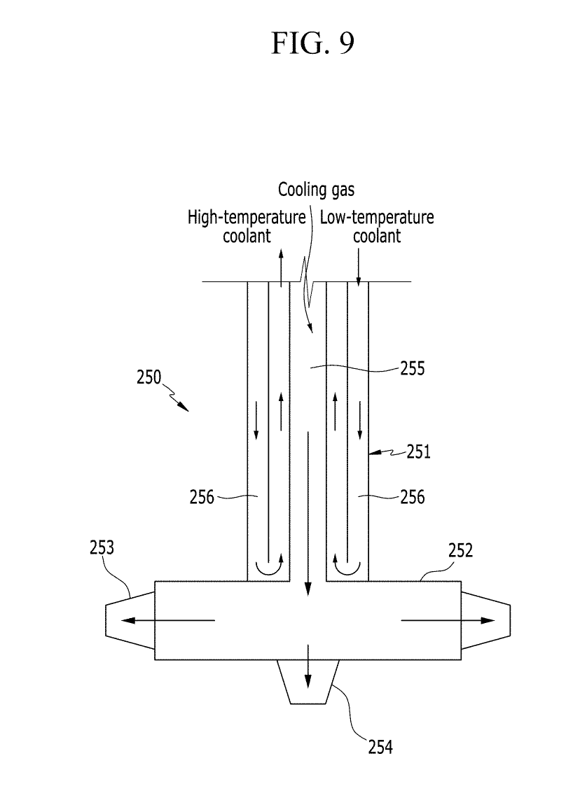

FIG. 9 is a cross-sectional view of the cooling spray nozzle applied to FIG. 8. For convenience, referring to FIG. 9, the pipe 251 is provided with a gas path 255 through which the cooling gas is supplied to the unit nozzle tips 253 and 254 and a coolant path 256 that cools the gas path 255.

The coolant path 256 is provided dually at an outer side of the gas path 255 and supplies a low-temperature coolant to cool the gas path 255, and the low-temperature coolant is circulated to become a high-temperature coolant while cooling the gas path 255 to cool the cooling gas supplied to the nozzle body 252. Thus, the cooling gas is sprayed to the silicon rod 40 formed around the rod bridge 31 while maintaining a low-temperature condition such that the upper portion of the silicon rod 40, in which the rod bridge 31 is provided, can be effectively cooled.

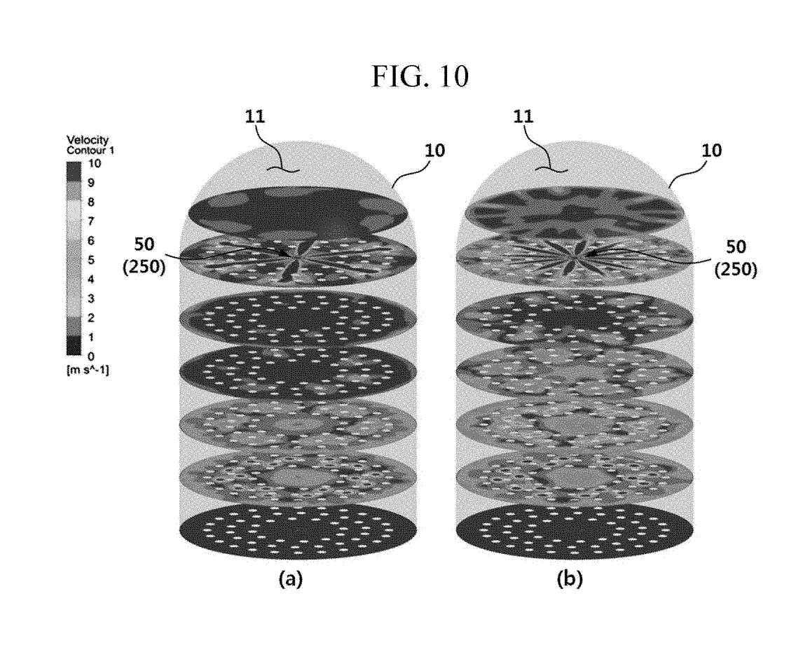

FIG. 10 shows a simulation result of gas speed distribution when cooling spray directions of the cooling spray nozzles applied to the polysilicon manufacturing apparatus according to the exemplary embodiment of the present invention are 6 directions (a) and 12 directions (b), respectively.

Referring to FIG. 10, in the cooling spray nozzles 50 (and 250), 6 of the unit nozzle tips 53 (and 253) are opened and a cooling gas (e.g., a cooling gas or a raw material gas) is sprayed in 6 equally spaced directions (a) on the plane, and 12 of the unit nozzle tips 53 (and 253) are opened and the cooling gas is sprayed in 12 equally spaced directions (b) on the plane. (a) and (b) show gas speed variation with respect to a perpendicular direction of the reaction chamber 11 of the reactor 10.

That is, in quantum comparison, the gas speed variation with respect to the vertical direction in the reaction chamber 11 of the reactor 10 is high in 6 directions (a) and low in 12 directions (b). That is, the gas speed variation is more uniform in 12 directions (b) compared to 6 directions (a).

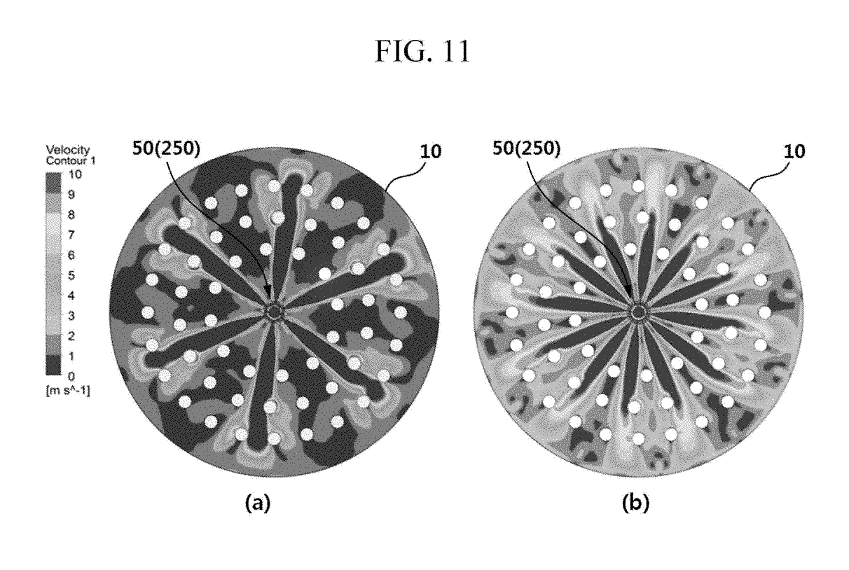

FIG. 11 shows a gas speed distribution diagram at the periphery of the cooling spray nozzle when the cooling spray direction of FIG. 10 is 6 directions (a) and 12 directions (b). Referring to FIG. 11, in the cooling spray nozzles 50 (and 250), 6 of the unit nozzle tips 53 (and 253) are opened and a cooling gas is sprayed in 6 equally spaced directions (a), and 12 of the unit nozzle tips 53 (and 253) are opened and the cooling gas is sprayed in 12 equally spaced directions (b). (a) and (b) show gas speed variation with respect to a horizontal direction of the reactor 10.

In quantum comparison, a part of the silicon rod receives a cooling effect and another part does not receive the cooling effect when the cooling spray is performed in the 6 directions (a), and most of the silicon rod receives the cooling effect when the cooling spray is performed in the 12 directions (b)

That is, the cooling effect distribution is more uniform when the cooling spray is performed in 12 directions (b) than in 6 directions (a). Accordingly, a cooling spray direction may be changed depending on a structure of a reactor 10 to be used.

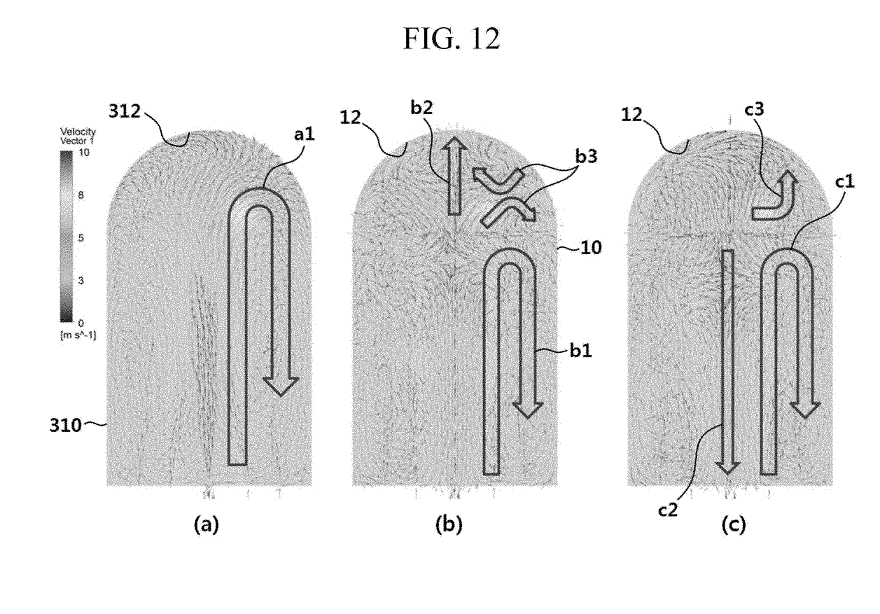

FIG. 12 shows a simulated gas vector distribution diagram provided for comparison of nozzle arrangements (b) and (c) according to the first and second exemplary embodiments of the present invention and a convention method (a).

Referring to FIG. 12, since the conventional method (a) does not include a cooling spray nozzle, a flow of a gas vector a1, which is as much as 3.35 m/s, is formed from a base (not shown) of a reactor 310 to a bell jar 312 as a raw material gas is supplied from the base of the reactor 310.

However, according to the first exemplary embodiment of the present invention, the cooling spray nozzle 50 is provided upwardly in the base 21, a flow of a gas vector b1, which is as much as 2.29 m/s, is formed from the base 21 of the reactor 10 to the cooling spray nozzle 50, a flow of another gas vector b2 that reaches the peak of the bell jar 12 of the reactor 10 is formed as the cooling gas is sprayed from the cooling spray nozzle 50, and a flow of another gas vector b3 that crosses an upper portion of the gas vector b1 between a flank side of the gas vector b2 and the bell jar 12 of the reactor 10 of the gas vector b2 is formed at an upper portion of the cooling spray nozzle 50.

As the gas flow vectors b2 and b3 are added by the cooling gas to the gas flow vector b1 formed by the raw material gas, an upper portion of the silicon rod 40 formed as silicon that is deposited around the rod bridge 31 can be effectively cooled.

In addition, when the cooling spray nozzle 250 according to the second exemplary embodiment of the present invention is provided downwardly in the reactor 10, a flow of a gas vector c1, which is as much as 2.09 m/s, is formed from the base 21 of the reactor 10 to the cooling spray nozzle 250, a flow of another gas vector c2 is formed from the base 21 to the cooling spray nozzle 250 as the cooling gas is sprayed from the cooling spray nozzle 250, and a flow of another gas vector c3 that reaches the cooling spray nozzle 250 from the peak of the bell jar 12 of the reactor 10, which is an upper portion of the cooling spray nozzle 250, is formed.

As the gas vectors c2 and c3 formed by the cooling gas are added to the gas vector v1 formed by the raw material gas, an upper portion of the silicon rod 40 formed as silicon that is deposited around the rod bridge 31 can be effectively cooled.

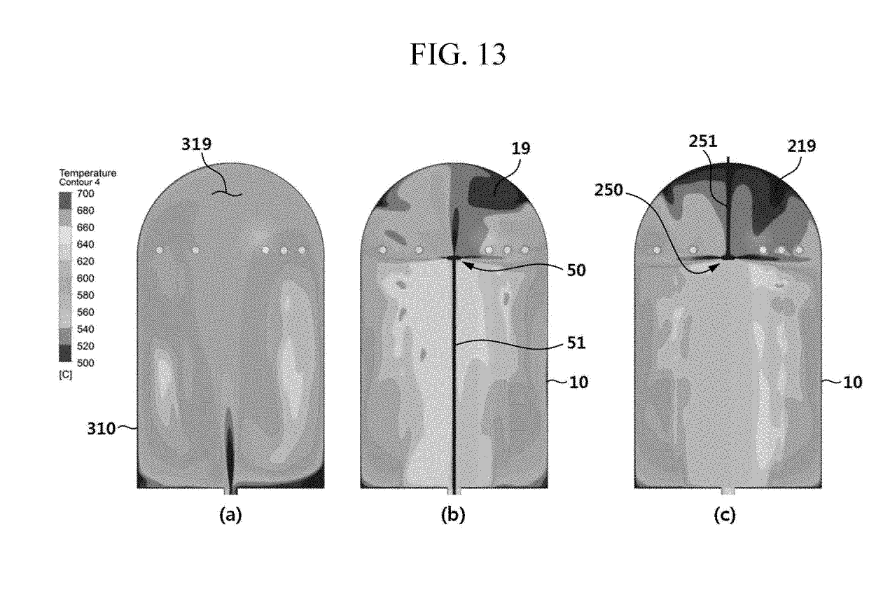

FIG. 13 shows a gas temperature distribution diagram provided for comparison of the cooling spray nozzle arrangements (b) and (c) according to the first and second exemplary embodiments of the present invention and a convention method (a).

Referring to FIG. 13, the lowest temperature is distributed in a base (not shown) of a rector 310 that supplies a raw material gas and the highest temperature is distributed in an upper portion 319 of the reactor 310 in the conventional method (a).

When the cooling spray nozzle 50 according to the first exemplary embodiment of the present invention is provided upwardly in the base 21, that is, in case of (b), the lowest gas temperature is distributed around the pipe 51 and in an upper portion 19 of the cooling spray nozzle 50. That is, the silicon rod 40 formed as silicon deposited around the rod bridge 31 can be effectively cooled.

In addition, when the cooling spray nozzle 250 according to the second exemplary embodiment of the present invention is provided downwardly, that is, in case of (c), the lowest gas temperature distribution is formed around the pipe 251 and in an upper portion 219 of the cooling spray nozzle 50. That is, the silicon rod 40 formed as silicon deposited around the rod bridge 31 can be effectively cooled.

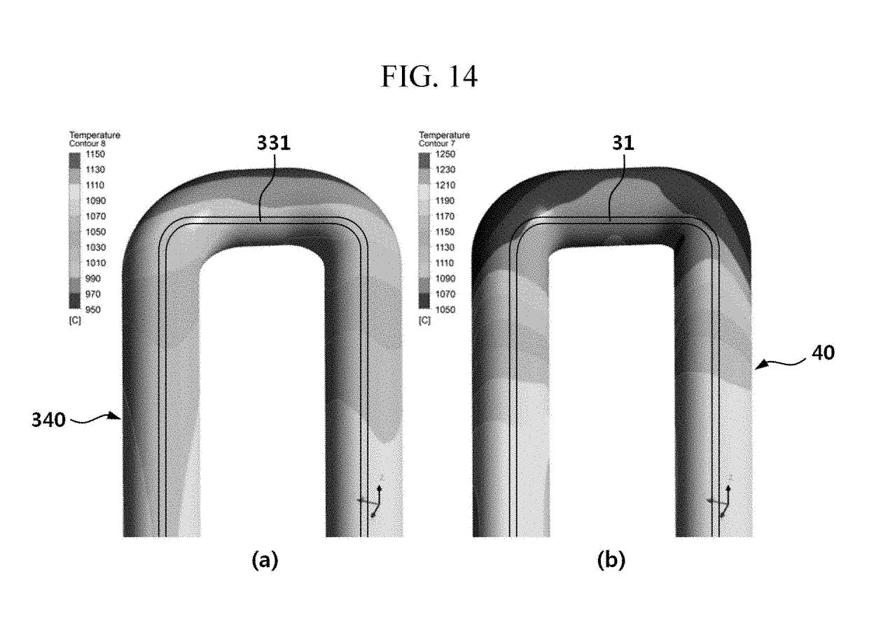

FIG. 14 shows a surface temperature distribution diagram of the silicon rod simulated for comparison of the cooling spray nozzle arrangement (b) according to the first and second exemplary embodiments of the present invention and a conventional method (a).

Referring to FIG. 14, compared to the surface temperature distribution of the silicon rod 340 in the conventional method (a), the surface temperature distribution of the silicon rod 40 is more decreased when the cooling spray nozzles 50 (and 250) according to the first and second exemplary embodiments of the present invention are provided.

Further, in the conventional method (a), compared to the surface temperature distribution of the periphery of the rod bridge 331 of the silicon rod 340, the surface temperature around the rod bridge 31 of the silicon rod 40 is more decreased when the cooling spray nozzles 50 and 250 according to the first and second exemplary embodiments of the present invention are provided. That is, under the same conditions, a temperature deviation between the upper portion and the lower portion of the silicon rod 340 is reduced in the first and second exemplary embodiments of the present invention compared to the conventional method, and therefore a temperature of the silicon rod 340 can be more increased. Accordingly, productivity can be improved and electrical intensity can be reduced in the first and second exemplary embodiments of the present invention.

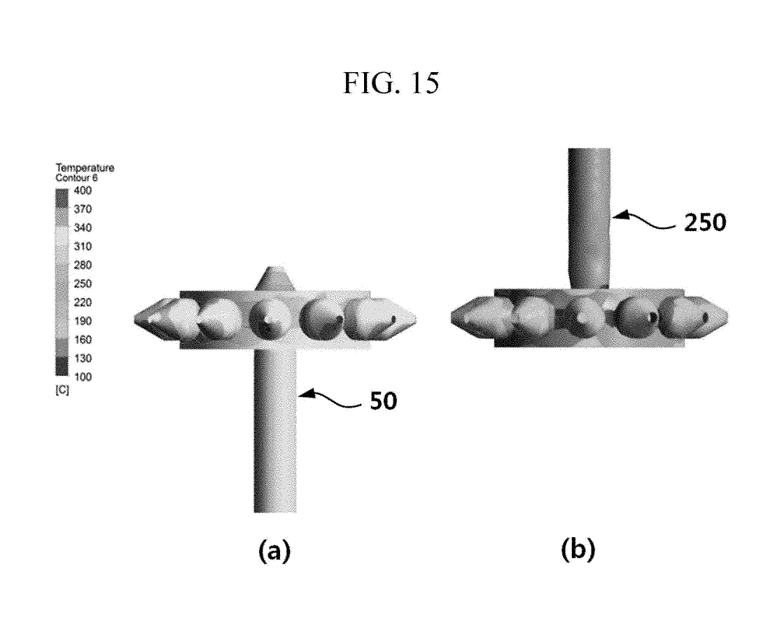

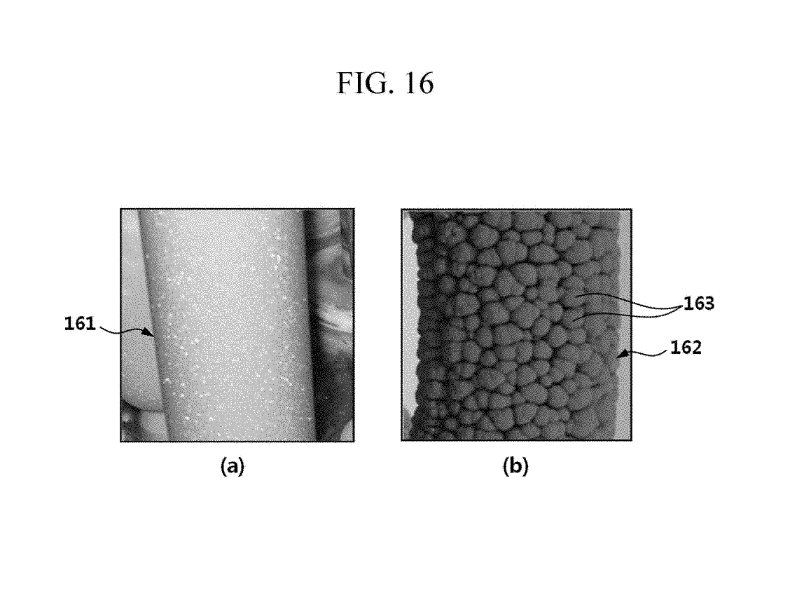

FIG. 15 shows a surface temperature distribution diagram of a temperature of a pipe and a temperature of a cooling spray nozzle, simulated in the cooling spray arrangements (a) and (b) according to the first and second exemplary embodiments of the present invention.

Referring to FIG. 15, the cooling spray nozzle 50 according to the first exemplary embodiment of the present invention is provided upwardly in the reaction chamber 11 of the reactor 10, and the cooling spray nozzle 250 according to the second exemplary embodiment of the present invention is provided in the bell jar 12 of the reactor and is lowered in the reaction chamber 11 of the reactor 10.

In comparison of the first exemplary embodiment of the present invention and the second exemplary embodiment of the present invention, a surface temperature (about 200° C.) of the cooling spray nozzle 250 of the second exemplary embodiment is lower than a surface temperature (about 300° C.) of the first exemplary embodiment. Thus, the cooling spray nozzle 250 that is provided downwardly in the bell jar 12 in the upper portion of the reactor 10 is more advantageous in supplying of the cooling gas to decrease the surface temperature around the rod bridge 31 of the silicon rod 40 than the cooling spray nozzle 50 that is provided upwardly in the base 21.

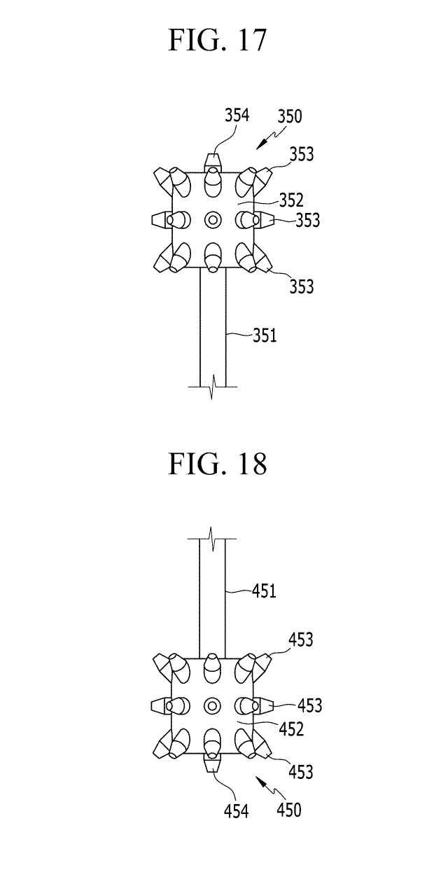

FIG. 17 is a side view of a cooling spray nozzle applied to a polysilicon manufacturing apparatus according to a third exemplary embodiment of the present invention, and FIG. 18 is a side view of a cooling spray nozzle applied to a polysilicon manufacturing apparatus according to a fourth exemplary embodiment of the present invention.

Referring to FIG. 17 and FIG. 18, pipes 351 and 451 are provided upward and downward in reactors or bases in cooling spray nozzles 350 and 450 of the third and fourth exemplary embodiments of the present invention. The pipe 351 may be provided upwardly in the base and the pipe 451 may be provided downwardly in the reactor.

Nozzle bodies 352 and 452 are connected to ends of the pipes 351 and 451 and each has a predetermined length along a height direction of each of the pipes 351 and 451. Unit nozzle tips 353 and 453 are arranged with a step difference set along length directions of the pipes 351 and 451 at external circumferences of the nozzle bodies 352 and 452.

In addition, like the unit nozzle tips 53 and 253 of the first and second exemplary embodiments of the present invention, the unit nozzle tips 353 and 453 of the third and fourth exemplary embodiments of the present invention are arranged along a circumferential direction at the external circumferences of the nozzle bodies 352 and 452. That is, in the third and fourth exemplary embodiments, the cooling spray nozzles 350 and 450 may spray a cooling gas within a predetermined range in a length direction of silicon rods.

Among the unit nozzle tips 353 and 453, unit nozzle tips provided in lower portions of the pipes 351 and 451 spray the cooling gas downwardly at a predetermined angle. Unit nozzle tips provided in upper portions of the pipes 351 and 451 spray the cooling pipe upwardly at a predetermined angle. In addition, unit nozzle tips disposed in centers of the pipes 351 and 451 spray the cooling gas in a horizontal direction.

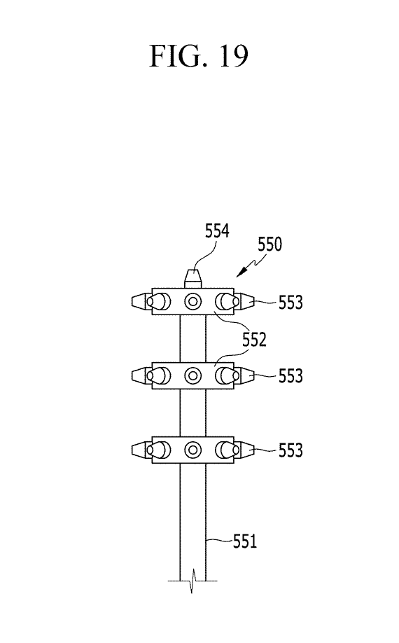

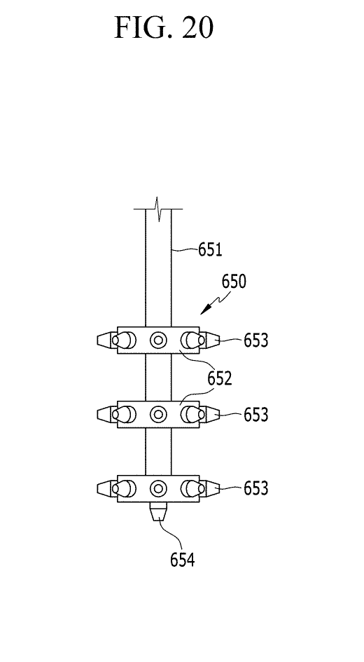

FIG. 19 is a side view of a cooling spray nozzle applied to a polysilicon manufacturing apparatus according to a fifth exemplary embodiment of the present invention, and FIG. 20 is a side view of a cooling spray nozzle applied to a polysilicon manufacturing apparatus according to a sixth exemplary embodiment of the present invention.

Referring to FIG. 19 and FIG. 20, cooling spray nozzles 550 and 650 according to the fifth and sixth exemplary embodiments of the present invention are provided upward and downward in reactors or bases. A pipe 551 is provided upward from the base, and a pipe 651 is provided downward in the reactor.

Nozzle bodies 552 and 652 are respectively provided in plural, and are arranged on the pipes 551 and 651 with a predetermined height difference in a height direction of each of the pipes 551 and 651. Unit nozzle tips 553 and 653 are arranged at a predetermined interval along an external circumference of each of the nozzle bodies 552 and 652 and spray a cooling gas. That is, in the fifth and sixth exemplary embodiments of the present invention, the cooling spray nozzles 550 and 650 can spray the cooling gas to a predetermined range in a length direction of each silicon rod.

In addition, the cooling spray nozzles 350, 450, 550, and 650 further include unit nozzle tips 354, 454, 554, and 654 that face upward or downward such that the cooling gas can be sprayed upwardly or downwardly like the unit nozzle tips 54 and 254 of the first and second exemplary embodiments of the present invention.

While this invention has been described in connection with what is presently considered to be practical example embodiments, it is to be understood that the invention is not limited to the disclosed embodiments, but, on the contrary, is intended to cover various modifications and equivalent arrangements included within the scope of the appended claims.

1. A polysilicon manufacturing apparatus comprising:
a reactor provided on a base and forming a reaction chamber;
a pair of feedthroughs provided in the base and extending into the reaction chamber;
rod filaments provided in the feedthroughs in the reaction chamber, connected with each other at upper ends thereof through a rod bridge, and where a silicon rod of polysilicon is formed from a raw material gas through a chemical vapor deposition (CVD) process; and
cooling spray nozzles spraying a cooling gas to the silicon rod formed as silicon deposited around the rod bridge and the rod filaments.

2. The polysilicon manufacturing apparatus of claim 1, wherein the cooling spray nozzle sprays the cooling gas to silicon deposited to the rod bridge from a lower flank side that is distanced by a predetermined gap from the rod bridge.

3. The polysilicon manufacturing apparatus of claim 1, wherein the cooling spray nozzles comprise:
pipes provided in upward and downward directions in the reactor or the base;
a plate-shaped nozzle body connected to an end of each pipe; and
unit nozzle tips provided at a predetermined interval along an external circumference of the nozzle body to spray the cooling gas.

4. The polysilicon manufacturing apparatus of claim 3, wherein the pipe is provided with at least one of gas inlets in the base and through which a raw material gas is injected or provided in the base separately from the gas inlets.

5. The polysilicon manufacturing apparatus of claim 3, wherein the pipe is provided upward in the base and connected with the nozzle body at an end of the pipe, and
the nozzle body further comprises unit nozzle tips that face upward at the opposite side of the pipe.

6. The polysilicon manufacturing apparatus of claim 3, wherein the pipe is provided downward in an upper portion of the reactor and connected with the nozzle body at an end of the pipe, and
the nozzle body further comprises unit nozzle tips that face downward at the opposite side of the pipe.

7. The polysilicon manufacturing apparatus of claim 3, wherein the pipe comprises:
a gas path supplying the cooling gas to the unit nozzle tips of the nozzle body; and
a coolant path provided dually at an external side of the gas path and cooling the cooling gas by circulating the coolant.

8. The polysilicon manufacturing apparatus of claim 1, wherein the cooling spray nozzle is formed of one of an Incoloy (Incoloy 800H, Incoloy 800), stainless steel (SS316L, SS316), and a Hastelloy.

9. The polysilicon manufacturing apparatus of claim 1, wherein the cooling spray nozzle sprays the cooling gas together with the raw material gas.

10. The polysilicon manufacturing apparatus of claim 1, wherein the cooling gas comprises H₂ or HCl.

11. The polysilicon manufacturing apparatus of claim 10, wherein the cooling gas further comprises a silane compound, which is one of dichlorosilane (DCS), trichlorosilane (TCS), monosilane, and silicon tetrachloride (STC).

12. The polysilicon manufacturing apparatus of claim 11, wherein the cooling gas formed of a raw material gas is supplied with a temperature that is lower than a surface temperature of the silicon rod.

13. The polysilicon manufacturing apparatus of claim 1, wherein the cooling spray nozzle comprises:
a pipe provided in upward and downward directions in the reactor or the base;
a nozzle body connected to an end of the pipe and having a predetermined length; and
unit nozzle tips arranged along an external circumference of the nozzle body with a height difference set in a length direction of the pipe and spraying the cooling gas.

14. The polysilicon manufacturing apparatus of claim 13, wherein, among the unit nozzle tips,
unit nozzle tips disposed in a lower portion of the pipe face downward at a predetermined angle,
unit nozzle tips disposed in an upper portion of the pipe face upward at a predetermined angle, and
unit nozzle tips disposed at a center of the pipe face a horizontal direction.

15. The polysilicon manufacturing apparatus of claim 1, wherein the cooling spray nozzle comprises:
a pipe provided in upward and downward directions in the reactor or the base;
nozzle bodies arranged on the pipe with a height difference set along a height direction of the pipe; and
unit nozzle tips arranged along an external circumference of the nozzle body at a predetermined interval and spraying the cooling gas.
